(19) United States
(12) Patent Application Publication
(10) Pub. No.: US 2018/0347071 A1
(43) Pub. Date: Dec. 6, 2018

(54) SYSTEMS AND METHODS FOR LOW-OXYGEN CRYSTAL GROWTH USING A DOUBLE-LAYER CONTINUOUS CZOCHRALSKI PROCESS

(71) Applicant: Corner Star Limited, Kowloon (HK)

(72) Inventor: Steven Lawrence Kimbel, St. Charles, MO (US)

(21) Appl. No.: 15/741,164

(22) PCT Filed: Jul. 21, 2016
(86) PCT No.: PCT/US2016/043367

§ 371 Date: Dec. 29, 2017

Related U.S. Application Data
(60) Provisional application No. 62/197,291, filed on Jul. 27, 2015.

(51) Int. Cl. C30B 15/12; C30B 29/06; C30B 15/00; C30B 15/20

(52) U.S. Cl. CPC C30B 15/12; C30B 15/20; C30B 15/002; C30B 29/06

(57) ABSTRACT

A method and system for double-layer continuous Cz crystal growing are disclosed. The system includes a crucible assembly including an inner crucible in an outer crucible, the inner crucible defining a growth region and a feed region, the crucible assembly containing molten material (e.g., silicon). The system also includes a susceptor, a continuous feed supply for providing a continuous feed to the feed region, and a temperature control system disposed about the susceptor and configured to cool a region of silicon at a bottom of the growth region to form a solid layer, the solid layer facilitating reducing an oxygen concentration in the growing crystal. The method includes separating molten material into the growth region and the feed region, initiating cooling at a bottom of the growth region, and solidifying a region of material at the bottom of the growth region, such that a solid layer is formed.

### CROSS-REFERENCE TO RELATED APPLICATION

This application claims priority to U.S. Provisional Patent Application No. 62/197,291 filed on 27 Jul. 2015, the entire disclosure of which is hereby incorporated by reference in its entirety.

### FIELD

The field relates generally to growing single- or top-seeded multi-crystal semiconductor or solar material by the Czochralski process, and in particular, to a double-layer continuous Czochralski (DLCCz) process.

### BACKGROUND

In solar wafer materials, such as for solar panels, the efficiency in producing energy may be adversely affected by the presence of oxygen in the wafer. For example, relatively high levels of oxygen (>10¹⁸ atoms/cm³) in an ingot of solar material may have an adverse effect on minority carrier lifetime and hence conversion efficiency of solar cells (silicon wafers) made from the ingot. Accordingly, the lower the oxygen concentration in the ingot, the better the conversion efficiency of a solar cell made from the ingot. In particular, a Light-Induced Defect (LID) may occur, by the pairing of oxygen with a dopant (e.g., boron in boron-doped silicon), which over time degrades the efficiency of the solar wafer and, therefore, the efficiency of the solar panel. In boron-doped silicon amount of such degradation is dependent upon both the oxygen concentration and the concentration of boron. In phosphorous-doped silicon, a high concentration of oxygen may generate oxygen precipitates in a solar cell, as the temperature of the solar cell increases. Such oxygen precipitates, referred to as “black heart” defects, degrade the performance of the solar cell. The amount of degradation is dependent upon the concentration and total surface area of the oxygen precipitates.

In a Czochralski (Cz) silicon crystal-growth process, silicon is introduced into a crucible and melted to produce a liquid silicon “melt”. In a batch Cz process, a single crucible is used and may be refilled multiple times to grow multiple crystals. In continuous Cz (CCz) designs, multiple concentric quartz crucibles are utilized to define various zones (e.g., an inner growth or melt zone and an outer melt zone), so that silicon growth and silicon feed melting may proceed simultaneously. The melt may be doped such that an n-type or p-type wafer may be produced, as desired. A seed crystal (or “seed”) is dipped into the melt and is slowly pulled upwards as it rotates. The seed subsequently grows, producing a cylindrical single-crystal ingot. The rate of pulling and the speed of rotation, as well as the temperature of the melt, affect the quality and size of the resulting crystal.

In Cz crystal growth, oxygen is transported into the silicon melt through dissolution of quartz from the crucible, and silicon dioxide (SiO₂) of the quartz becomes mobile silicon and oxygen atoms or loosely bonded silicon plus oxygen, or SiO. The oxygen either evaporates from the melt surface or is taken up into the growing crystal as an interstitial species. The level of uptake in the ingot is a function of the equilibrium oxygen concentration in the melt. Uptake into the growing crystal depends on a segregation coefficient, or a ratio of the concentration of oxygen in the melt to oxygen in the crystal, which is approximately unity.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

In one aspect, a double-layer continuous Cz (DLCCz) crystal growing system includes a crucible assembly having an inner crucible disposed within an outer crucible. The inner crucible defines a growth region surrounding a growing crystal and a feed region between the inner crucible and the outer crucible. The crucible assembly contains molten material. The system also includes a susceptor containing the crucible assembly and a continuous feed supply for providing a continuous feed of feedstock to the feed region. The system further includes a temperature control system disposed about the susceptor and configured to cool a region of material at a bottom of the growth region to form a solid layer, the solid layer facilitating reducing an oxygen concentration in the growing crystal.

In another aspect, a method for double-layer continuous Cz crystal growing includes separating molten material into at least a growth region surrounding a growing crystal and a feed region for continuously receiving feedstock. The method also includes initiating cooling at a bottom of the growth region, and solidifying a region of material at the bottom of the growth region such that a solid layer is formed. The solid layer facilitates reducing an oxygen concentration in the growing crystal.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 shows a schematic view of an example embodiment of a Double-Layer Continuous Czochralski (DLCCz) system.

FIG. 2 shows a schematic view of an alternate embodiment of the DLCCz system shown in FIG. 1.

### DETAILED DESCRIPTION

As described briefly above, in continuous Czochralski (CCz) crystal growth, the melt is supplemented by a continuous silicon feed at the same time that the crystal is growing. This process is in contrast to “batch” crystal growth, in which the melt depleted by completion of crystal growth and is subsequently recharged or re-filled to start a new crystal growth. In either case, the melt can be supplemented either with solid feedstock (e.g., small granules or chips of solid silicon) or molten feedstock, in which solid silicon is pre-melted before being introduced into the system.

Magnetic Czochralski (MCz or MCCz) crystal growth is characterized by the use of a magnetic field to, among other things, suppress oxygen levels in the growing crystal. The magnetic field, which may be oriented axially, along a cusp, or horizontally in different variations, increases the effective viscosity of the melt in directions normal to the lines of magnetic flux. Accordingly, flow of the melt in those directions is relatively limited. In some MCz designs, flow of the melt from a region nearest the wall of the crucible (where oxygen-producing reactions are highest) is limited. However, due to the size of outer crucibles required for a double-crucible configuration in many MCz/MCCz designs, the magnets may need to be large, and thus, may be very expensive.

Other methods for decreasing the presence of oxygen in the grown crystal include attempts to decrease the melt-to-quartz dissolution boundary surface area (i.e., “wetted area”). In a deep or high-aspect-ratio crucible, the ratio of melt surface area to melt area in contact with quartz is relatively small (<1), such that the equilibrium oxygen concentration is relatively high. By contrast, in a shallow or low-aspect-ratio crucible, the ratio is close to unity, and thus the equilibrium oxygen concentration is relatively low with attendant benefits to minority carrier lifetime and cell photovoltaic conversion efficiency due to the small light degradation.

Additionally, attempts have been made to freeze or solidify a layer of the silicon melt adjacent the bottom interior surface of the crucible. This process, a Double-Layer Czochralski (DLCz) process, has been shown to yield reduced oxygen levels with little or no magnetic field, reducing the cost of traditional MCz designs. In a batch process, however, a portion of the melt is consumed, so ingot lengths are limited. In addition, there is a risk that as the melt is depleted by the growing crystal, the crystal may solidify with the frozen silicon layer on the bottom.

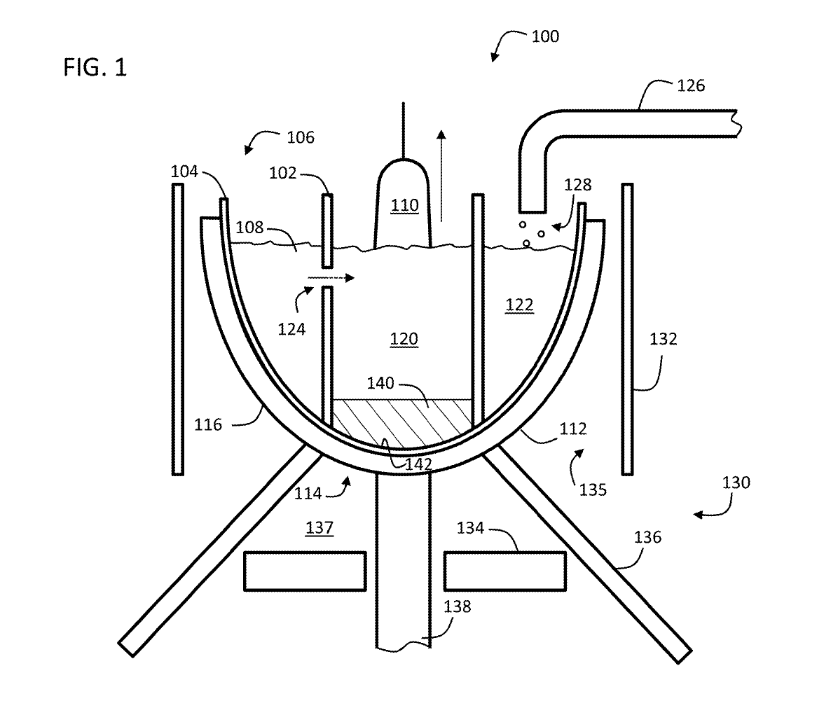

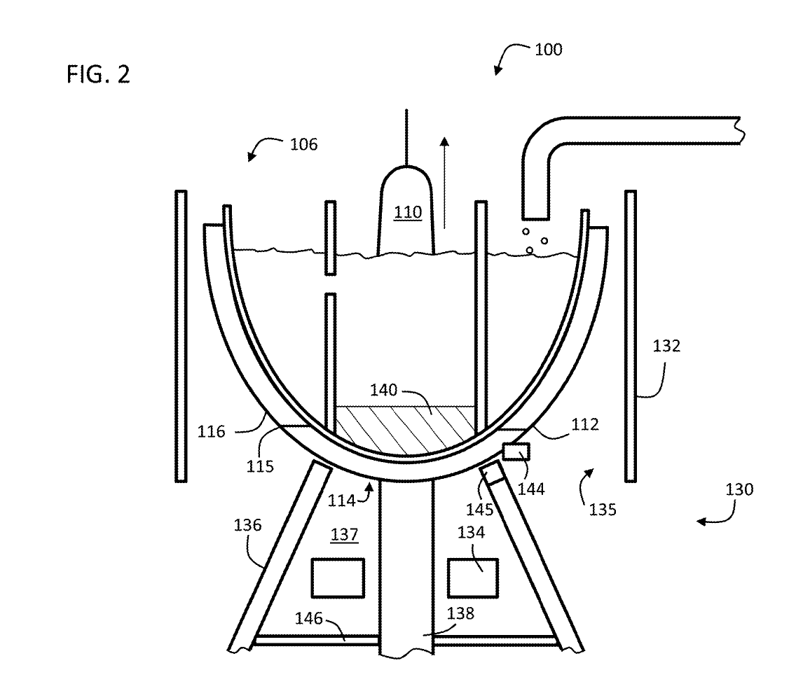

Referring now to the Figures, in FIG. 1, a schematic view of an example embodiment of a Double-Layer Continuous Czochralski (DLCCz) system 100 is provided. In FIG. 2, a schematic view of an alternate embodiment of the DLCCz system 100 is provided. An inner crucible 102 holds a quantity of molten material 108, such as silicon, from which a single crystal ingot 110 is grown and pulled in a vertical direction indicated by an arrow relative to the silicon melt 108. In the example embodiment, the inner crucible 102 is disposed within and concentric with an outer crucible 104. Collectively, the inner crucible 102 and outer crucible 104 form a crucible assembly 106. In the example embodiment, the inner crucible 102 is fused to the outer crucible 104 by a hermetic seal to avoid damage to the crucible assembly 106 during the freezing of a solid layer 140 of silicon in the inner crucible 102, as will be described more fully herein. In alternate embodiments, the inner crucible 102 and the outer crucible 104 may be installed in the DLCCz system 100 as separate (i.e., unconnected) crucibles. In some embodiments, the crucibles 102, 104 may be cylindrical. As described herein, the crucibles 102, 104 may be made of, for example, a quartz material.

The crucible assembly 106 is contained in a susceptor 112, made from a high-temperature resistant material, which is used to contain and support the crucible assembly 106. Such a high-temperature resistant material may include, for example, carbon fiber, carbon fiber composite, SiC-converted graphite, graphite, or combinations thereof. In some embodiments, the susceptor 112 has a unitary construction (i.e., the susceptor 112 is a single piece of material). In other embodiments, a base 114 of the susceptor 112 may be separate from or differently constructed than (e.g., made of a different material than) a side wall 116 of the susceptor 112, to reduce lateral conduction of heat from the base 114 to the side wall 116. For example, the side wall 116 may be separated from the base 114 by an insulating material 115 (as shown in FIG. 2).

The inner crucible 102 defines a growth region 120 within the inner crucible 102 and a melt supplement region 122 between the inner crucible 102 and the outer crucible 104. The melt supplement region 122 may also be referred to herein as a “feed region” 122. One or more passageways 124, disposed below a surface of the melt 108, connect the feed region 122 to the growth region 120. The crucible assembly 106 controls mixing of introduced silicon feed material and dopant in the feed region 122 such that the ratio of dopant in the feed region 122 to dopant in the growth region 120 is near the segregation coefficient for dopants having low evaporation and segregation coefficients near unity, such as boron, in order to control doping of the growing crystal 110.

A flow of an inert gas, such as Argon, is typically provided along the length of the growing crystal 110. The details of a Czochralski growth chamber are well known and are omitted for the sake of simplicity. In addition, a continuous feed supply 126 provides a quantity of silicon feedstock 128 at a steady rate to the melt supplement region 122 of the crucible assembly 106. The silicon feedstock 128 may be in the form of solid chunks or granules of silicon feedstock 128 provided directly to the melt supplement region 122, or may alternatively be pre-melted before being provided to the melt supplement region 122.

In the example embodiment, a temperature control system 130 is disposed around an exterior of the susceptor 112. The temperature control system 130 may include side heaters 132, which are disposed around the side wall 116 of the susceptor 112, and base heaters 134, arranged below the base 114 of the susceptor 112. Any or all of the side and base heaters 132, 134 may be planar or annular resistive heating elements, or other suitably shaped heating elements. Further, any or all of the side and/or base heaters 132, 134 may be independently controlled to generate separate heating zones, with each heating zone corresponding to the thermal output of a separate heater 132, 134. It will be appreciated that the temperature control system 130 may thus facilitate providing optimal thermal distribution across the system 100. In some embodiments, there may be only one annular side heater 132 that extends substantially fully around the side wall 116 of the susceptor 112. In other embodiments, there may be any number of side heaters 132. Likewise, in some embodiments, there may be only one base heater 134, and in other embodiments, there may be any number of base heaters 134.

In the example embodiment, the side heaters 132 are separated from the base heaters 134 by an insulator 136 that extends radially outward from the base 114 at an angle. Accordingly, the insulator 136 may partially define a first temperature zone 135 that includes the side heater(s) 132 and that extends substantially radially outwards from the side wall 116, and a second temperature zone 137 that includes the base heater 134 and that extends substantially below the base 114. In one embodiment, the insulator 136 may be attached to susceptor 112, as shown in FIG. 1. In an alternative embodiment, as shown in FIG. 2, the insulator 136 may be fully supported by a separate structure (e.g., a lower graphite support, not shown) and extend close to the susceptor base 114 having little or no contact therewith.

The insulator 136 is positioned such that the base 114 of the susceptor 112 is in the second temperature zone 137, separate from the first temperature zone 135 around the side wall 116 of the susceptor 112, which allows for the base 114 to be held at a different (e.g., lower) temperature without affecting the temperature of the liquid silicon melt 108, as will be described further herein. In other embodiments, the insulator may have other orientations, positions, shapes, and/or configurations, and still function to thermally separate the first temperature zone from the second temperature zone. For example, the insulator may additionally or alternatively include a horizontal plate, a cylinder about the base, or a cone.

In addition, the susceptor 112 is supported by a pedestal 138. In some embodiments, the pedestal 138 is made of a suitable material such that the pedestal 138 enhances the transfer of heat from the base 114 of the susceptor 112 (and, thus, the bottom of the crucible assembly 106). Such materials may include solid graphite (e.g., if a high heat transfer is desired) or a thin sleeve of graphite (e.g., a graphite felt or rigid graphite insulation) encircling an insulating material. As such, the pedestal 138 may be an element of the temperature control system 130.

In one embodiment, as shown in FIG. 2, the temperature control system 130 includes active cooling features such as a radiation window 146. The radiation window 146 may be mechanically opened, for example, to a room-temperature environment or to introduce a liquid-cooled element to the susceptor 112, either automatically or manually, to induce cooling of the second temperature zone 137. Additionally or alternatively, active temperature control of the second temperature zone 137 may be adjusted by manipulating the insulator 136 (for example, by removing a portion of the insulator 136 to expose the second temperature zone 137 to a cooled environment) and/or by increasing or reducing the heat output of the base heater 134. Similarly, active temperature control of the first temperature zone 135 may be adjusted by increasing or reducing the heat output of the side heater 132. Any or all of the temperature control by temperature control system 130 may be automated.

In the example embodiment, the second temperature zone 137 at the base 114 of the susceptor 112 causes the formation of a solid (i.e., frozen) layer 140 of silicon adjacent the bottom of the crucible assembly 106. The solid layer 140 serves to decrease an amount of oxygen entering the growing crystal 110 by covering the bottom of the inner crucible 102 and thereby reducing the quartz-melt boundary 142 (“dissolution boundary” 142) surface area, and also reducing quartz debris generated from bubbles, pits, and other inner crucible 102 defects. The solid layer 140 may be contained within the inner crucible 102 and, therefore, within the growth region 120 of the crucible assembly 106. Such containment may be preferable, as there may be little to no benefit to freezing any of the melt 108 in the feed region 122. In other embodiments, the solid layer 140 may extend into the feed region 122 of the crucible assembly 106. Such extension may, however, in some cases, be detrimental to the function of the system 100. For example, if the feedstock 128 is in a solid state, solidifying the melt 108 from both the top and the bottom of the melt 108 may decrease the efficiency and/or efficacy of the system 100.

In the example embodiment, before formation of the solid layer 140, all silicon 108 in the crucible assembly 106 may be melted. Subsequent to this melting, solidification of the solid layer 140 may begin during formation of the neck, crown, or body of the crystal 110 during the crystal growth process. In the example embodiment, solidification may begin during the crown or the neck phase of growing the crystal 110, such that the solid layer 140 is formed before growth of the body of the crystal 110 to minimize the presence of oxygen therein. In other embodiments, solidification may begin during growth of the body. In some embodiments, the initiation of the solidification (i.e., cooling of the second temperature zone 137, at the base 114 of the susceptor 112) may be automated, using Programmable Logic Controllers and cameras as well as temperature sensors (e.g., temperature monitors 144, shown in FIG. 2) monitoring the crystal growth. In other embodiments, the solidification may be initiated manually (e.g., by a human operator monitoring the crystal growth process).

The degree of solidification may be determined by careful monitoring of the melt level measurement and the material balance. Additionally or alternatively, ultrasonic methods may be used to measure the degree of solidification (e.g., the thickness of the solid layer 140). A short-duration “ping” of sound energy may be released into the crucible assembly 106 (e.g., through the pedestal 138 and/or base 114 of the susceptor 112) and the “time of flight” or return time from transmission to receipt of the reflection may be used to generate multiple distance measurements to indicate a thickness of the solid layer 140.

The DLCCz system 100 described herein facilitates decreasing the oxygen content in the growing crystal 110, which may improve upon traditional Cz, CCz, and/or DLCz systems. Notably, the addition of a continuous feed 126, 128 greatly reduces or eliminates the risk that the growing crystal 110 will solidify to the solid layer 140, because hot, molten silicon 108 is replenished between the solidifying crystal 110 and the solid layer 140 at the bottom of the melt 108. Additionally, the combination of a double-layer process and a continuous process improves the viability and efficiency of batch-type DLCz systems as an economical way to produce low-oxygen-level silicon crystals 110. The solid layer 140 of silicon in the inner crucible 102 decreases the production of oxygen at the dissolution boundary 142 between the quartz crucible 102 and the melt 108, as it effectively covers the entire bottom of the growth region 120 with an oxygen barrier, reducing the dissolution boundary 142 surface area to the side wall of the inner crucible 102. Accordingly, it may be beneficial to provide a shallow, large-diameter inner crucible 102 that increases the ratio of the melt 108 surface area to the dissolution boundary 142 surface area. A larger evaporation surface of the melt 108 increases the evaporation of any mobile oxygen, which in turn decreases oxygen uptake into the growing crystal 110. However, a large-diameter inner crucible 102 may necessitate a large-diameter outer crucible 104, which may increase the cost of the system 110. As such, a balance between cost and oxygen reduction may be considered when choosing the diameter of the crucibles 102, 104 in the crucible assembly 106.

Likewise, the depth of the melt 108 may be a consideration. As described above, for a given melt 108 surface evaporation area and condition, reducing the dissolution boundary 142 surface area of the inner crucible 102 decreases the oxygen levels in the growing crystal 110. A shallow melt 108 may therefore be preferred. However, a shallow melt 108 increases the risk that the crystal 110 may freeze onto the solid layer 140. Such risk may be mitigated by ensuring that the continuous feed addition 126, 128 into the feed region 122 matches the feed output into the growing crystal 110, or by maintaining a deeper melt 108. The passageway(s) 124 between the growth region 120 and the feed region 122 may be located nearer to the surface of the melt 108, whether the melt 108 is shallow or deep, than in conventional CCz systems to reduce the risk of “freezing shut” of the passageways 124 during use of the system 100. The flow of the molten silicon 108 during continuous crystal growth may also help maintain the passageway 124 in an open configuration.

The insulator 136 allows for the simultaneous freezing or solidifying of the solid layer 140 and maintenance of the melt 108 in a liquid state. In addition the insulator 136, along with control of the base heater 134, limit the growth of the solid layer 140 upwards into the melt 108. However, active heating and cooling may further enhance the maintenance of the silicon in two discrete states. Accordingly, one or more temperature monitors 144 (shown in FIG. 2), such as for example a pyrometer, thermocouple, or another suitable temperature measurement component, is included in the system 100. The temperature monitor 144 enables the temperature control system 130 to manipulate temperature of the first and/or second temperature zones 135, 137 as necessary to maintain the melt 108 in its liquid state and the solid layer 140 in its solid state. For example, the temperature control system 130 may adjust the power output of at least one of the side and base heaters 132, 134 based on an output of the temperature monitor 144 (e.g., if the temperature of one of the first and second temperature zones 135, 137 reaches a predefined limit or threshold).

In the example embodiment, the temperature monitor 144 is positioned outside the second temperature zone 137 with a view path to the base 114 of the susceptor 112 through a vacuum barrier window 145. In other embodiments, the temperature monitor may be otherwise positioned. For example, in one embodiment, the temperature monitor may include a thermocouple that is fixed within the second temperature zone. In one embodiment, the system 100 may include a fixed element such as an annular ring (not shown) that is positioned close to the base 114 of the susceptor 112, such that the fixed element has a similar temperature as the susceptor 112, or the temperature of the fixed element changes with the temperature of the susceptor 112. The thermocouple may thus be attached to the fixed element and may indirectly monitor the temperature of the susceptor 112.

In addition, passive cooling of the susceptor base 114 may further facilitate maintenance of the respective temperature of the first and second temperature zones 135, 137. As described above, the susceptor base 114 may be sufficiently separate from the side wall 116 (as a separate piece, as different material integrally formed to the side wall 116, or separated by an insulating material 115) such that the base 114 and/or the second temperature zone 137 may be maintained at a separate, cooler temperature more easily. Also, as described above, the pedestal 138 may help conduct heat away from the susceptor base 114 (passively or actively), which is beneficial in that the thermal transfer may occur directly below the location of the solid layer 140 in the second temperature zone 137.

During melt extraction from a Cz system, it may be desirable to minimize the quantity of uncontaminated silicon removed and to maximize the concentration of contaminants removed. In the example embodiment, melt extraction from the system 100 may be performed by allowing the solid layer 140 to grow into the melt 108 (i.e., allow more of the melt 108 to solidify) before extraction. Accordingly, having the passageways 124 located near the surface of the melt 108 aids in preventing the passageway 124 from “freezing shut” during extraction.

Embodiments of the disclosure facilitate Cz crystal growth of silicon with reduced oxygen levels. By providing a continuous feed of silicon into the system, viability and efficiency of at least some known Cz systems, such as the control of resistivity, total silicon yield, and the fraction of total usable low-oxygen product by a double-layer Cz process, is improved.

It should be understood that although the embodiments described herein illustrate a DLCCz process for silicon crystal growth, other single- and poly-crystalline materials and compounds, including germanium, may be used without departing from the scope of the present disclosure.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A double-layer continuous Cz (DLCCz) crystal growing system, the system comprising:
a crucible assembly comprising an inner crucible disposed within an outer crucible, the inner crucible defining a growth region surrounding a growing crystal and a feed region between the inner crucible and the outer crucible, the crucible assembly containing molten material;
a susceptor containing the crucible assembly;
a continuous feed supply for providing a continuous feed of feedstock to the feed region; and
a temperature control system disposed about the susceptor and configured to cool a region of material at a bottom of the growth region to form a solid layer, the solid layer facilitating reducing an oxygen concentration in the growing crystal.

2. The DLCCz crystal growing system of claim 1, wherein the temperature control system comprises:
a base heater;
a side heater; and
an insulator, wherein the insulator thermally insulates the base heater from the side heater.

3. The DLCCz crystal growing system of claim 2, wherein the insulator partially defines a first temperature zone including the side heater and a second temperature zone including the base heater.

4. The DLCCz crystal growing system of claim 2, wherein the side heater is an annular side heater that extends fully around the outer crucible.

5. The DLCCz crystal growing system of claim 1, wherein the temperature control system includes a selectively openable radiation window.

6. The DLCCz crystal growing system of claim 1, wherein the temperature control system includes a pedestal for passively cooling a base of the susceptor.

7. The DLCCz crystal growing system of claim 1, wherein the temperature control system is configured to initiate cooling before body growth of the growing crystal.

8. The DLCCz crystal growing system of claim 1, wherein the susceptor includes a side wall and a base, the base being separate from the side wall.

9. The DLCCz crystal growing system of claim 8, wherein the side wall is separated from the base by an insulating material.

10. The DLCCz crystal growing system of claim 1, wherein the molten material is silicon.

11. A method for double-layer continuous Cz crystal growing, the method comprising:
separating molten material into at least a growth region surrounding a growing crystal and a feed region for continuously receiving solid material feedstock;
initiating cooling at a bottom of the growth region; and
solidifying a region of molten material at the bottom of the growth region such that a solid layer is formed, the solid layer facilitating reducing an oxygen concentration in the growing crystal.

12. The method of claim 11, wherein the molten material is silicon.

13. The method of claim 11, further comprising providing a temperature control system including a base heater, a side heater, and an insulator, wherein the insulator thermally insulates the base heater from the side heater.

14. The method of claim 13, wherein the side heater is an annular side heater.

15. The method of claim 13, wherein the temperature control system further includes a selectively openable radiation window.

16. The method of claim 13, wherein the temperature control system further includes a pedestal, wherein the pedestal facilitates passive cooling of the bottom of the growth region.

17. The method of claim 13, wherein the temperature control system further includes a temperature monitor, and wherein the insulator at least partially defines a first temperature zone including the side heater and a second temperature zone including the base heater, the method further comprising adjusting a temperature of the second temperature zone based on an output from the temperature monitor.

18. The method of claim 11 further comprising initiating the solidifying before body growth of the growing crystal.

19. The method of claim 11 further comprising providing a susceptor for supporting a crucible assembly, wherein the crucible assembly defines the growth region and the feed region, and wherein the susceptor includes a side wall and a base, the base being separate from the side wall to further facilitate the solidifying.

20. The method of claim 19, wherein the susceptor side wall and base are separated by an insulating material.
